(19) United States
(12) Patent Application Publication
(10) Pub. No.: US 2006/0221590 A1
(43) Pub. Date: Oct. 5, 2006

(54) System and method for Advanced Mezzanine Card connection

(76) Inventors: Edoardo Campini, Mesa, AZ (US); Andy Saffarian, Scottsdale, AZ (US); Marwan Khoury, San Jose, CA (US)

Correspondence Address: Grossman, Tucker, Perreault & Pfleger, PLLC;c/o PortfolioIP, P.O. Box 52050, Minneapolis, MN, 55402, US

(21) Appl. No.: 11/096,089

(22) Filed: Mar. 31, 2005

(51) Int. Cl. H05K 1/14

(52) U.S. Cl. 361/803; 361/796

(57) ABSTRACT

A method according to one embodiment may include providing a circuit board having a connector footprint including a plurality of electrical contacts and providing a mezzanine card including a first plurality of conductive traces on a first side of the mezzanine card. The method of this embodiment may also include providing a first wiring board disposed between at least a portion of the circuit board and at least a portion of the mezzanine card. The first wiring board may electrically couple at least a portion of the electrical contacts of the connector footprint to at least a portion of the conductive traces of the mezzanine card. Of course, many alternatives, variations, and modifications are possible without departing from this embodiment.

### FIELD

The present disclosure relates to a system, apparatus, and method for coupling a card mezzanine card to a circuit board.

### BACKGROUND

In computer systems, computer component cards may be connected to a single base or carrier board that plugs into a computer bus or data path. The component cards may be stacked on the base or carrier board and are commonly referred to as mezzanine cards. An Advanced Mezzanine Card (AMC) is a high-speed, hot-swappable mezzanine card that is compatible with, but not limited to, use with Advanced Telecommunications Computing Architecture (ATCA) carriers. The AMC standard is designed to enhance modularity and high-speed serial connectivity for ATCA and other platforms. AMC cards may use high speed interconnect standards such as PCI Express, which provides a high speed serial connection.

The hot-swappable nature of AMC cards may provide useful functionality. In many applications, however, hot-swappability is not an important or even necessary feature. Specialized connectors are required to facilitate the hot-swappable characteristic of AMC cards. Frequently support structures, such as rails, are also included to enable and/or facilitate the hot-swappable feature of AMC cards. Connectors and support structures necessary to allow hot-swappability of AMC card may add to the cost of utilizing AMC cards. Furthermore, the hot-swappable AMC connectors provide a standardized spacing between stacked AMC cards and/or between an AMC card and a carrier board. The standard spacing of the AMC connectors dictates the maximum height of components that can be included on an AMC card and/or airflow pathways around the AMC card and/or components on and AMC card.

### BRIEF DESCRIPTION OF DRAWINGS

Features and advantages of the claimed subject matter will be apparent from the following detailed description of embodiments consistent therewith, which description should be considered with reference to the accompanying drawings, wherein:

FIG. 1 schematically depicts a computer system capable of housing a circuit board and card consistent with the present disclosure;

FIG. 2 is a schematic illustration of a circuit board consistent with the present disclosure;

FIG. 3 is a detailed view of a portion of a circuit board consistent with the present disclosure showing a connector footprint;

FIG. 4 schematically depicts a connector portion of a card consistent with the present disclosure;

FIG. 5 is a side elevation view of a carrier board and card assembly consistent with the present disclosure;

FIG. 6 is a perspective view of a carrier board and card assembly consistent with the present disclosure; and

FIG. 7 representationally depicts and embodiment of a portion of a first side of a first wiring board including a plurality of electrical contacts corresponding to a connector footprint of a circuit board and a plurality of conductive pathways;

FIG. 8 depicts an embodiment of a portion of a second side of a first wiring board including a first plurality of electrical contacts corresponding to conductive traces of a card and a second plurality of electrical contacts capable of being coupled to corresponding electrical contacts of a third wiring board;

FIG. 9 is a schematic cross-sectional view of an anisotropic conductive system that may suitably be employed consistent with the present disclosure;

FIG. 10 is a plan view of an anisotropic conductive system that may suitably be employed consistent with the present disclosure; and

FIG. 11 is an embodiment of a frame that may suitably be employed in connection with the present disclosure.

Although the following Detailed Description will proceed with reference being made to illustrative embodiments, many alternatives, modifications, and variations thereof will be apparent to those skilled in the art. Accordingly, it is intended that the claimed subject matter be viewed broadly.

### DETAILED DESCRIPTION

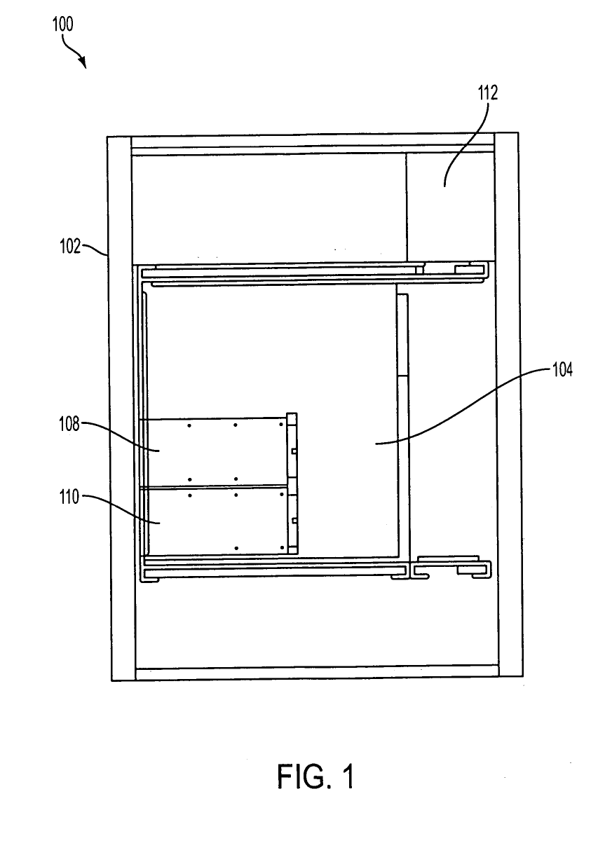

With reference to FIG. 1, an embodiment of a computer system 100 is depicted. The computer system 100 may generally include a chassis 102 housing one or more circuit boards 104 such that the circuit board 104 may be at least partially disposed in the chassis 102. The circuit board 104 may be mechanically and/or electrically coupled to the chassis 102. One, or more, smaller circuit boards, or cards (e.g., a mezzanine card), 108 and 110 may be electrically and/or physically coupled to the circuit board 104. The cards 108, 110 may also include various components, such as a processor, memory module, or other component. The system 100 may additionally include one or more fans 112 associated with a cooling system. The fans 110 may produce a flow of air through the chassis 102 to provide convective cooling of the circuit boards 104, cards 108, 110 and/or other components disposed within the chassis 102. According to one embodiment the chassis 102 may be an advanced telecommunications computing architecture (advanced TCA or ATCA) chassis, complying with, or compatible with, PCI Industrial Computer Manufacturers Group (PICMG), Advanced Telecommunications Computing Architecture (ATCA) base specification, PICMG 3.0 revision 1.0, published Dec. 30, 2002.

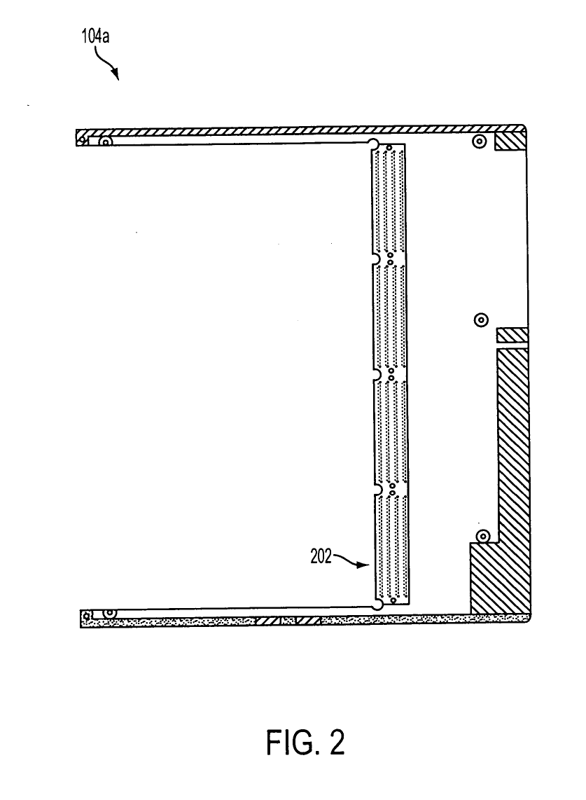

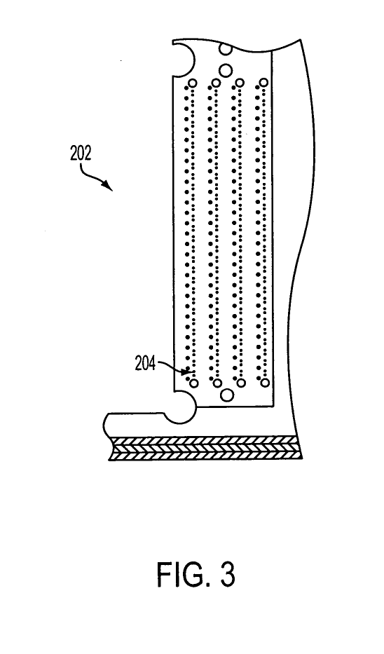

Turning to FIG. 2, an embodiment of a circuit board 104a is schematically depicted. As previously mentioned, the circuit board 104a may be capable of being electrically and/or mechanically coupled to one or more cards. Accordingly, the circuit board 104a may include at least one or more card connector footprints 202. As shown in the detailed illustration of FIG. 3, each of the connector footprints 202 may include a plurality of electrical contacts 204, generally, capable of being electrically coupled to a card connector (not shown). Each of the plurality of electrical contacts 204 in the connector footprint 202 may be provided as a landing pad, i.e., a conductive pad disposed on and/or exposed on the surface of the circuit board 104a. In various alternative embodiments, the electrical contacts may be provided as plated through holes and/or other known features for electrically coupling components to a circuit board.

In an embodiment herein, the circuit board 104a may be configured to be electrically coupled to an advanced mezzanine card (AMC) complying with and/or compatible with PCI Industrial Computer Manufacturers Group (PICMG), Advanced Mezzanine Card (AMC) Base Specification, PICMG AMC.0 revision 1.0, published Jan. 3, 2005 (the “AMC Specification”). As such, the connector footprint 202 and the electrical contacts 204 may be configured to be electrically coupled to an AMC connector, such as basic B or AB connector or an extended B+ or A+B+ connector. According to other embodiments, the circuit board may be configured to be coupled to various cards in addition to cards complying with and/or compatible with the AMC Specification. The number of electrical contacts and the arrangement of the electrical contacts may be provided to comply with the appropriate technical specifications for the circuit board and/or for the card.

The circuit board 104a depicted in FIG. 2 is generally configured as a carrier board. As depicted, the carrier board may include a plurality of card connector footprints each capable of being coupled to a card connector. Each card connector may be capable of being mechanically and/or electrically coupled to at least one card, such as an AMC. Such a carrier board may electrically and/or mechanically couple at least one such card to a computer system. Consistent with additional and/or alternative embodiments, the circuit board may also include various additional components, such as processors, memory modules, communications modules, etc. in addition to being capable of being coupled to one or more cards. Furthermore, the circuit board may be provided as an ATCA circuit board or blade capable of being electrically and/or mechanically coupled in an ATCA chassis. According to various alternative embodiments, a circuit board consistent with the present disclosure may be capable of being electrically and/or mechanically coupled to various computer systems other than and/or in addition to ATCA computer systems.

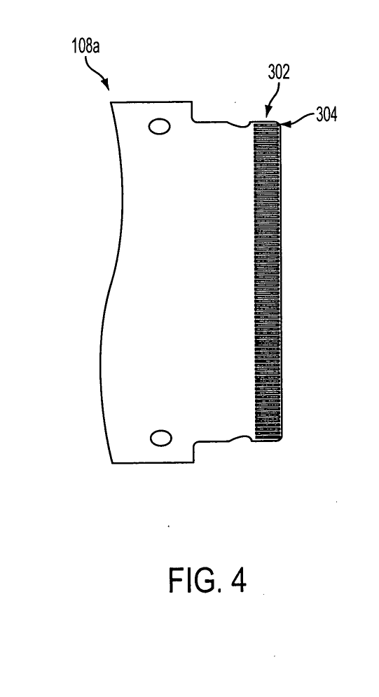

Turning to FIG. 4, a connector portion 302 of an embodiment of a card 108a is depicted. Consistent with the prior description, the card 108a may be capable of being coupled to the circuit board 104. The card 108a may include various components (not shown) such as processors, memory, etc., that may interact with one or more components disposed on and/or associated with the circuit board 104. According to various additional and/or alternative embodiments one or more components disposed on and/or associated with the card 108a may be coupled to a computing system via the circuit board 104.

In an embodiment, the connector portion 302 of the card 108a may include a plurality of conductive traces 304, generally. The conductive traces 304 may include, for example, metallic regions on and/or exposed to the surface of the card 108a. The conductive traces 304 may be capable of providing electrical connection between any components and/or circuits disposed on and/or associated with the card 108a and a circuit board and/or computer system. The size, number, and location of the conductive traces may be provided in accordance with the relevant technical specification for the card 108a. The illustrated embodiment depicts a plurality of conductive traces disposed on one side of the card. Consistent with a further embodiment, the card may be provided having at least one conductive trace on one and/or both sides of the card.

According to an embodiment herein the card may be a card complying with and/or compatible with the AMC Specification. In such an embodiment the conductive traces in the connector portion of the card may be provided having a configuration suitable for use with a basic B/AB connector configuration and/or an extended B+/A+B+ connector configuration, as defined by the AMC Specification. Consistent with the present disclosure, the card may comply with a technical specification other than the AMC Specification. In such embodiments the conductive traces may be provided having various other configurations complying with technical standards other than the AMC Specification.

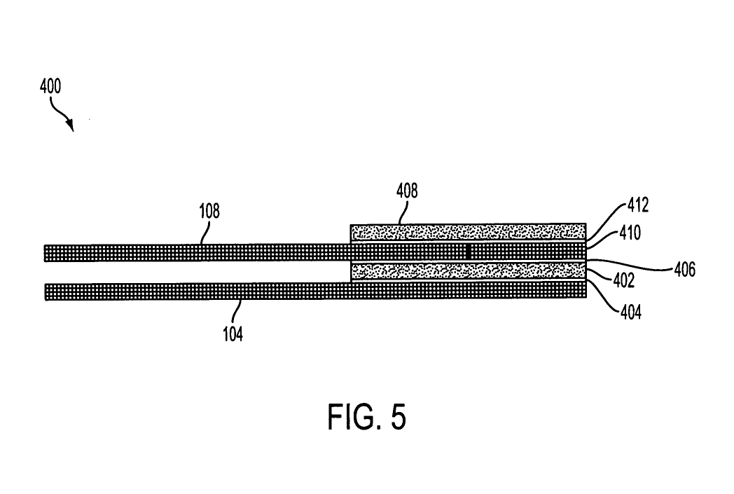

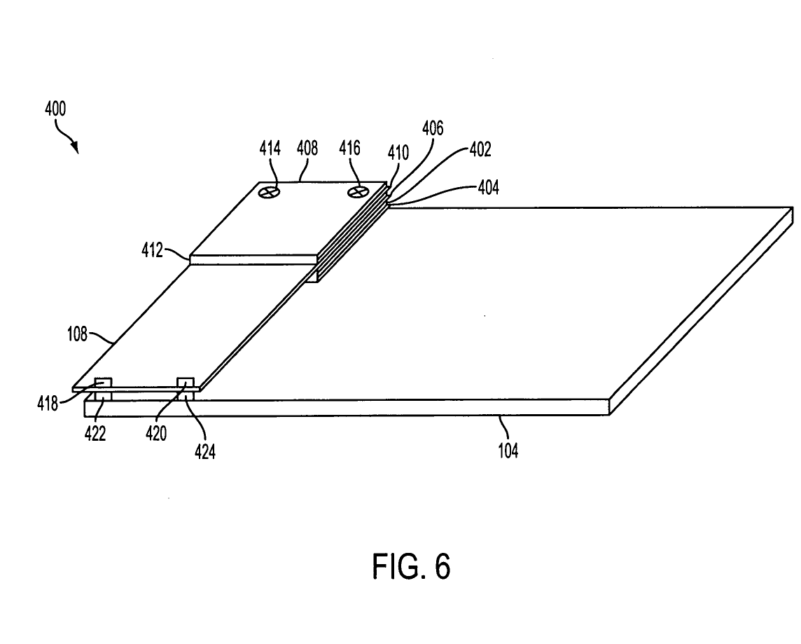

Turning to FIGS. 5 and 6, an embodiment of a circuit board/card assembly 400 is depicted. As shown, the card 108 may be capable of being coupled to a circuit board 104 via a first wiring board 402. The circuit board 104 may include a connector footprint including a plurality of contacts as previously described with reference to FIGS. 2 and 3. Similarly, the card 108 may include a connector portion including a plurality of conductive traces as described with reference to FIG. 4. The contacts of the first wiring board 402 may be capable of being electrically coupled to the conductive traces of the card by the wiring board, thereby electrically coupling the card 108 and the circuit board 104. As used in any embodiment herein, a wiring board may be any circuit board and/or substrate capable of supporting at least one electrical contact and/or at least one conductive pathway.

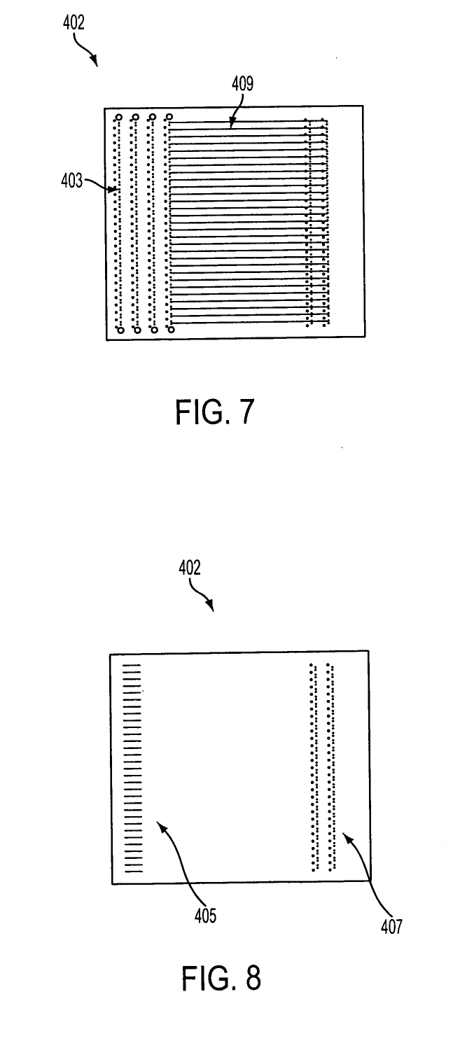

With reference to FIGS. 7 and 8, in an embodiment, the first wiring board 402 may include a first plurality of electrical contacts 403 on a first side adjacent to the circuit board and corresponding to the contacts 204 of the connector footprint 202 of the circuit board 104. The corresponding contacts 403 on the first side of the wiring board 402 may be capable of being electrically coupled to the contacts 202 of the connector footprint 204 on the circuit board 104. The first wiring board 402 may also include a first plurality of electrical contacts 405 on a second side of the first wiring board 402. The first plurality of electrical contacts 403 on the first side of the wiring board 402 may be capable of being electrically coupled to the first plurality of electrical contacts 405 on the second side of the wiring board 402.

In one embodiment, at least a portion of the first plurality of electrical contacts 405 on the second side of the wiring board may correspond to conductive traces 304 on at least one side of the card 108 facing the circuit board 104. The first plurality of electrical contacts 405 on the second side of the wiring board 402 corresponding to the conductive traces 304 facing the circuit board may be capable of being electrically coupled to the conductive traces 304 of the card. In this manner, at least a portion of the electrical contacts, e.g. 204, included in the connector footprint 202 of the circuit board 104 may be electrically coupled to at least a portion of the conductive traces 304 included on the card 108.

In one embodiment, the first wiring board 402 may be electrically coupled to the circuit board 104 and/or the card 108 via anisotropic conductive layers 404, 406. In one specific embodiment, the anisotropic conductive layers 404, 406 may include an anisotropic conductive polymer material or film. The anisotropic conductive polymer layers 404, 406 may include anisotropic conductive elastomer, adhesive, film, etc. capable of conducting an electric current through the thickness of the layer with little or no conduction along the length and/or width of the layer. The anisotropic conductive layer may conduct current between corresponding contacts of the circuit board and wiring board and between corresponding contacts of the wiring board and card with little or no conduction to offset contacts

At least a portion of the plurality of electrical contacts 204 included in the connector footprint 202 of the circuit board 104 may be electrically coupled to one or more conductive traces disposed on the card 108 facing away from the circuit board 104. According to one such embodiment, a second wiring board 408 may be provided having a plurality of electrical contacts (not shown) that are capable of being electrically coupled to one or more of the conductive traces disposed on the card 108 facing away from the circuit board 104. The electrical contacts of the second wiring board 408 capable of being electrically coupled to the conductive traces facing away from the circuit board 104 may be electrically coupled to the contacts 204 included in the connector footprint 202 of the circuit board 104.

In an embodiment herein, at least a portion of the electrical contacts 403 included on the first wiring board 402, corresponding to the electrical contacts 204 of the connector footprint 202 of the circuit board 104, may be coupled to a second plurality of electrical contacts 407 on the second side of the first wiring board 402. As depicted, at least a portion of the electrical contacts 403 on the first side of the first wiring board 402 may be coupled to the second plurality of electrical contacts 407 on the second side of the first wiring board 403 via a plurality of conductive pathways 409 disposed on the first wiring board 402, and/or a plurality of through-board conductive pathways. The conductive pathways 409 may be disposed on the first and/or the second side of the first wiring board 402.

A third wiring board 410 may include a plurality of electrical contacts on the first side of the third wiring board 410. At least a portion of the plurality of electrical contacts on the first side of the third wiring board 410 may be capable of being electrically coupled to the second plurality of electrical contacts 407 on the second side of the first wiring board 402. Similar to the first wiring board 404, the third wiring board 410 may include a plurality of electrical contacts on a second side of the third wiring board that are electrically coupled to at least a portion of the plurality of electrical contacts on the first side of the third wiring board 410. In one embodiment, at least a portion of the plurality of electrical contacts on the first side of the third wiring board 410 may be electrically coupled to at least a portion of the plurality of electrical contacts on the second side of the third wiring board 410 via conductive pathways and/or through-board conductors disposed on and/or associated with the third wiring board 410. Accordingly, at least a portion of the plurality of electrical contacts on the second side of the third wiring board 410 may be capable of being electrically coupled to at least a portion of the second plurality of electrical contacts 407 on the second side of the first wiring board 402 via the plurality of electrical contacts on the first side of the third wiring board 410.

At least a portion of the plurality of electrical contacts on a second side of the third wiring board 410 that may be capable of being electrically coupled to the second plurality of electrical contacts on the second wiring board 408. As mentioned above, at least a portion of the plurality of electrical contacts on the second side of the third wiring board 410 may be electrically coupled to a plurality of electrical contacts on the first side of the third wiring board 410. Accordingly, the second plurality of electrical contacts on the second wiring board 408 may be capable of being coupled to the plurality of electrical contacts on the first side of the third wiring board 410 via the electrical contacts on the second side of the third wiring board 410.

At least a portion of the first plurality of electrical contacts of the second wiring board 408 may be capable of being coupled to conductive traces disposed on the card 108 facing away from the circuit board 104 may be electrically coupled to a second plurality of electrical contacts on the second wiring board located at least partially outside of the perimeter of the card 108. According to one embodiment, the first plurality of electrical contacts of the second wiring board may be coupled to the second plurality of electrical contacts of the second wiring board by conductive pathways on the second wiring board, similar to the conductive pathways included on the first wiring board.

Consistent with the foregoing, one or more conductive traces on the card 108 facing away from the circuit board 104 may be capable of being coupled to one or more contacts 204 included in the connector footprint 202 included on the circuit board 104. At least a portion of the first plurality of electrical contacts of the second wiring board 408 may be capable of being coupled to conductive traces disposed on the card 108 facing away from the circuit board 104. The first plurality of electrical contacts of the second wiring board 408 may be coupled to a second plurality of electrical contacts on the wiring board 408. At least a portion of the second plurality of electrical contacts on the second wiring board 408 may be capable of being coupled to a plurality of electrical contacts on a second side of a third wiring board 410. The plurality of electrical contacts on the second side of the third wiring board 410 may be coupled to a plurality of contacts on the first side of the third wiring board 410. At least a portion of a second plurality of electrical contacts 407 on a second side of the first wiring board 402 may be capable of being coupled to at least a portion of the electrical contacts on the first side of the third wiring board 410. The second plurality of electrical contacts 407 on the second side of the first wiring board 402 may be coupled to a plurality of electrical contacts 403 on the first side of the first wiring board 402. At least a portion of the electrical contacts 403 on the first side of the first wiring board 402 may be capable of being coupled to one or more electrical contacts 204 in a connector footprint 202 included on the circuit board 104. In the foregoing manner, at least a portion of the electrical contacts 204 of the connector footprint 202 on the circuit board 104 may be capable of being coupled to one or more of the conductive traces on the card 108 facing away from the circuit board 104.

In the illustrated embodiment of FIG. 6, at least a portion of the first wiring board 402 and the second wiring board 408 may extend outside of the perimeter of the card 108. As depicted, the third wiring board 410 may be generally inline with the card 108. In such a configuration, the first wiring board 402 may overlie at least a portion of the circuit board 104. The card 108 and the third wiring board 410 may each overlie at least a portion of the first wiring board 402. The second wiring board 408 may overlie at least a portion of the card 108 and at least a portion of the third wiring board 410.

As previously mentioned, the first wiring board 402 may be electrically coupled to each of the circuit board 104 and the card 108 via respective anisotropic conductive layers 404, 406. In a similar manner, the first wiring board 402 may also be electrically coupled to the third wiring board 410 via the second anisotropic conductive layer 406. A third anisotropic conductive layer 412 may be disposed overlying at least a portion of the card 108 and the third wiring board 410. The third anisotropic conductive layer 412 may, accordingly, electrically coupled the third wiring board 410 and the second wiring board 408. The third anisotropic conductive layer 412 may also electrically couple the second wiring board 408 and the card 108.

According to one aspect, the separation between the card 108 and the circuit board 104 may be varied by varying the thickness of the first wiring board 402. In further embodiments, a plurality of wiring boards may be provided in a stacked assembly and disposed between the card and the circuit board. The stacked assembly of wiring boards may provide a cumulative thickness and a corresponding separation between the card and the circuit board. The separation between the card and the circuit board may be provided, for example, based on component heights on the card and/or airflow pathways between the card and/or components on the card and adjacent features. Similar to the illustrated assembly of the circuit board 104, the first wiring board 402, and the card 108, individual wiring boards in a stacked wiring board assembly disposed between the circuit board and the card may be electrically coupled to one another using one or more layers of anisotropic conductive material. Adjacent surfaces of adjacent wiring boards in a stacked assembly may include corresponding electrical contacts. The anisotropic conductive material may be disposed between adjacent wiring boards of the stacked configuration. The layers of anisotropic conductive material may provide an electrical pathway between the corresponding electrical contacts of the adjacent wiring boards.

Consistent with the illustrated embodiment, the stacked arrangement of the circuit board 104, first wiring board 402, card 108, third wiring board 410, and second wiring board 408 may be assembled using fasteners 414, 416. In an embodiment herein, the fasteners 414, 416 may be screws. Various alternative mechanical fasteners may also be employed for assembling the circuit board/card assembly 400. In one embodiment, the circuit board 104, first wiring board 402, second siring board 408, and third wiring board 410 may each include holes for receiving the fasteners 414, 416 therethrough. In addition to receiving the fasteners 414, 416, the holes may also index the circuit board 104 and wiring boards 402, 408, 410 allowing facile alignment of the various corresponding electrical contacts. According to one aspect, the fasteners 414, 416 may provide sufficient compression of the circuit board 104 and wiring boards 402, 408, 410 to achieve electrical coupling of corresponding electrical contacts. An embodiment consistent with the preceding description may provide facile assembly of a circuit board, card, and associated wiring boards.

According to one embodiment, the card 108 may generally be maintained in position by the compressive and/or spring force of the second wiring board 408 bearing against the card 108. In such an embodiment, the card 108 may generally be clamped between the first wiring board 402 and the second wiring board 408. The clamp force of the second wiring board 408 and the first wiring board 402 may be sufficient to maintain the card 108 electrically coupled to the first wiring board 402 and the second wiring board 408. In a further embodiment, the clamping force provided by the second wiring board 408 may be sufficient to physically retain the card 108 in position between the second wiring board 408 and the first wiring board 402. In another embodiment, at least one fastener, such as a screw, may pass through an opening in the card. Such a mechanical fastener may secure the card in position and/or further ensure electrical coupling between conductive traces on the card and corresponding electrical contacts on the first and/or second wiring boards.

According to another aspect, the circuit board/card assembly 400 may include additional mechanical fasteners 418, 420 which may couple the card 108 to the circuit board 104. The fasteners 418, 420 may assist in maintaining the card 108 in position sandwiched between the first wiring board 402 and the second wiring board 408. Furthermore, in part, the fasteners 418, 420 may index the card 108 relative to the circuit board 104 and/or one or more of the wiring boards 402, 408, 410. In this manner, the fasteners 418, 420 may maintain the conductive traces of the card 108 in position relative to the corresponding electrical contacts of the first and/or second wiring boards 402, 408.

Spacers 422, 424 may be disposed between the card 108 and the circuit board 104. The spacers 422, 424 may reduce and/or eliminate deflection of the card 108 toward the circuit board 104. Deflection of the card 108 may result from mechanical loads applied to the card 108. Deflection of the card 108 as a result of mechanical loads experienced by the card 108 may result in movement of the card 108 relative to the circuit board 104 and/or relative to the wiring boards 402, 408, 410 and or breakage or damage of the card 108. Movement of the card 108 relative to the circuit board 104 and/or relative to the wiring boards 402, 408, 410 may result in a loss of electrical coupling between the card and the circuit board 104 and/or one of the wiring boards 402, 408, 410. Employing spacers 422, 424 to reduce and/or eliminate deflection of the card 108 towards and/or away from the circuit board 104 may facilitate maintaining electrical connection between the card 108 and the circuit board 104 and/or one or more of the wiring boards 402, 408, 410. Additionally, employing spacers 422, 424 to reduce and/or eliminate deflection of the card 108 may reduce and/or eliminate associated damage to the card 108.

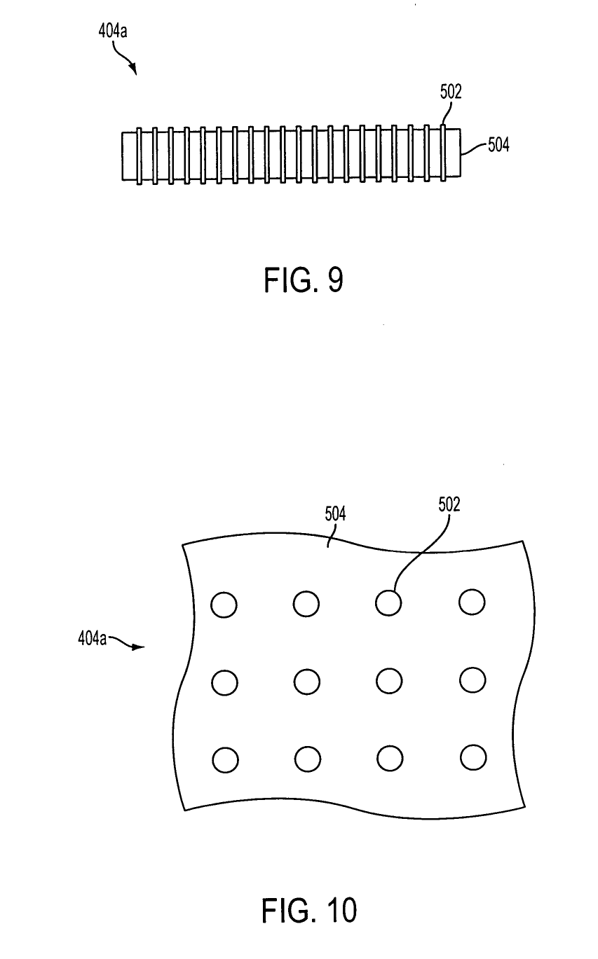

Numerous anisotropic conductive materials, often call Z-axis materials, are known. As shown in FIGS. 9 and 10, one variety of such anisotropic conductive material 404a may include a plurality of conductive elements 502 extending through a matrix of a polymer material 504. The conductive elements 502 may include conductive filaments or similar features. Adjacent conductive elements may be insulated from one another by the matrix of polymer material 504. Accordingly, an electrical current may be conducted through the thickness of the material 404a, i.e., the Z-axis of the material. The separation and insulation of adjacent conductive elements 502 by matrix of polymer material 504 may reduce and/or prevent the conduction of a current in the X and Y axis of the material. In one specific embodiment, the individual conductive elements may have an average diameter on the order of tens of microns and a separation on the general order of 100 microns. However, the scope of the present disclosure should not be construed as limited by the diameter and/or separation of the conductive elements. Furthermore, various other configurations of anisotropic conductive materials are known and may suitably be employed in connection with the present disclosure.

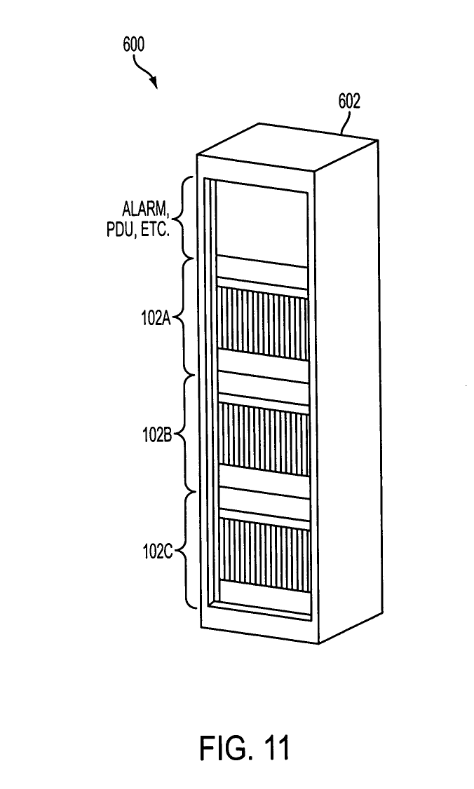

Referring to FIG. 11, a system 600 consistent with the present disclosure is illustrated. As depicted, the system 600 may include a frame 602. The frame 602 may accommodate and electrically couple a plurality of chassis 102A, 102B, and 102C. One or more of the chassis 102A, 102B, 102C may include at least one circuit board which may be coupled to at least one card consistent with any embodiment described herein. The frame 602 may include, for example, a power supply for providing power to each of the individual chassis 102A, 102B, 102C disposed in the frame 602, etc. Additionally, as mentioned above, the frame 602 may electrically couple one or more of the chassis 102A, 102B, 102C to at least one other chassis.

According to an alternative embodiment, rather than being disposed in a common frame, a system consistent with the present disclosure may include a plurality of chassis that may be individually hardwired to one another. One or more of the plurality of chassis may include at least one circuit board coupled to at least one card consistent with any embodiment described herein. Additionally, each of the plurality of chassis may be powered by an individual power supply and/or may be separately powered by a common power supply. Such a system may, therefore, provide a greater freedom in the physical arrangement and interrelation of the plurality of chassis.

Consistent with the foregoing, a card may be electrically and/or physically coupled to a circuit board without the use of a dedicated connector. In one specific embodiment, a hot-swappable card, such as a card complying with and/or compatible with the AMC Specification, may be coupled to a circuit board in a non-hot-swappable manner, thereby eliminating the need and/or use of an AMC connector. While the use of an AMC connector may be eliminated consistent with the present disclosure, a circuit board configured for use with a card complying with and/or compatible with the AMC Specification may be employed without modifying the circuit board from a standard connector footprint. Eliminating the use of an AMC connector may decrease the cost of incorporating the card onto the circuit board. Furthermore, by eliminating the AMC connector greater freedom in placement of the card relative to the circuit board may be realized. For example, the spacing of the card relative to the circuit board may be customized without being restricted to positioning dictated by a standard AMC connector. Accordingly, it may be possible to employ greater height components on a card than would be possible using a standard AMC connector. Similarly, airflow passages around the card may be adjusted and/or adapted to specific needs without consideration of the card placement relative to the circuit board dictated by standard AMC connectors.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Other modifications, variations, and alternatives are also possible. Accordingly, the claims are intended to cover all such equivalents.

What is claimed is:

1. A system comprising:
a frame comprising at least one Advanced Telecommunications Computing Architecture (ATCA) chassis;
a circuit board at least partially disposed within said chassis, said circuit board comprising a connector footprint comprising a plurality of electrical contacts;
an Advanced Mezzanine Card (AMC) comprising a first plurality of conductive traces on a first side of said AMC; and
a first wiring board to electrically couple at least a portion of said plurality of electrical contacts of said connector footprint to at least a portion of said plurality of conductive traces of said AMC.

2. A system according to claim 1, further comprising a first anisotropic conductive material disposed between said circuit board and said first wiring board, said first anisotropic conductive material electrically coupling said circuit board to said first wiring board, and further comprising a second anisotropic conductive material disposed between said first wiring board and said AMC, said second anisotropic conductive material electrically coupling said first wiring board to said AMC.

3. A system according to claim 1, wherein said AMC further comprises a second plurality of conductive traces disposed on a second side of said AMC, and wherein said system further comprises a second wiring board to electrically couple at least a portion of said second plurality of conductive traces to at least a portion of said plurality of electrical contacts of said connector footprint.

4. A system according to claim 3, further comprising a third wiring board coupled between at least a portion of said second wiring board and at least a portion of said first wiring board, said second wiring board electrically coupling at least a portion of said second plurality of conductive traces to at least a portion of said plurality of electrical contacts of said connector footprint via said third wiring board and said first wiring board.

5. A system according to claim 3, further comprising a first anisotropic conductive material electrically coupling said circuit board to said first wiring board, a second anisotropic conductive material electrically coupling said first wiring board to said third wiring board, and a third anisotropic conductive material electrically coupling said third wiring board to said second wiring board.

6. A system according to claim 5, said third anisotropic conductive material further electrically coupling said second wiring board to at least a portion of said second plurality of conductive traces.

7. An apparatus comprising:
a circuit board comprising a connector footprint comprising a plurality of electrical contacts;
a mezzanine card comprising a first plurality of conductive traces on a first side of said mezzanine card; and
a first wiring board to electrically couple at least a portion of said plurality of electrical contacts of said connector footprint to at least a portion of said conductive traces of said mezzanine card.

8. An apparatus according to claim 7 wherein said first wiring board comprises a first plurality of electrical contacts on a first side of the first wiring board and a first plurality of electrical contacts on a second side of said first wiring board, wherein at least a portion of said first plurality of electrical contacts on the first side are electrically coupled to at least a portion of said electrical contacts of said connector footprint and at least a portion of the first plurality of electrical contacts on the second side are electrically coupled to at least a portion of said first plurality of conductive traces, and wherein at least a portion of said first plurality of electrical contacts on the first side of said first wiring board are electrically coupled to at least a portion of the first plurality of electrical contacts on said second side of the first wiring board.

9. An apparatus according to claim 8, further comprising a first anisotropic conductive material disposed between at least a portion of said circuit board and at least a portion of said wiring board, said first anisotropic conductive material electrically coupling at least a portion of said plurality electrical contacts of said connector footprint and at least a portion of said first plurality of electrical contacts on the first side of said first wiring board.

10. An apparatus according to claim 8, further comprising a second anisotropic conductive material disposed between at least a portion of said first wiring board and at least a portion of said mezzanine card, said second anisotropic material electrically coupling at least a portion of said first plurality of electrical contacts on said second side of said first wiring board to at least a portion of said plurality of conductive traces.

11. An apparatus according to claim 7, wherein said mezzanine card comprises a second plurality of conductive traces disposed on a second side of said mezzanine card, said apparatus further comprising a second wiring board electrically coupling at least a portion of said second plurality of conductive traces to at least a portion of said electrical contacts of said connector footprint.

12. An apparatus according to claim 11, further comprising a third wiring board coupled between said second wiring board and said first wiring board, said second wiring board electrically coupling at least a portion of said second plurality of conductive traces to at least a portion of said electrical contacts of said connector footprint via said third wiring board and said first wiring board.

13. An apparatus according to claim 7, wherein said mezzanine card comprises an Advanced Mezzanine Card (AMC).

14. An apparatus according to claim 7, wherein said circuit board comprises an Advanced Telecommunications Computing Architecture (ATCA) circuit board.

15. An apparatus according to claim 7, wherein said first wiring board comprises a thickness to provide a variable separation between said circuit board and said mezzanine card.

16. A method of comprising:
providing a circuit board comprising a connector footprint comprising a plurality of electrical contacts;
providing a mezzanine card comprising a first plurality of conductive traces on a first side of said mezzanine card; and
providing a first wiring board disposed between at least a portion of said circuit board and at least a portion of said mezzanine card, said first wiring board electrically coupling at least a portion of said electrical contacts of said connector footprint with at least a portion of said conductive traces of said mezzanine card.

17. A method according to claim 16, further comprising providing a first anisotropic material disposed between at least a portion of said circuit board and at least a portion of said first wiring board, and providing a second anisotropic material disposed between at least a portion of said first wiring board and at least a portion of said mezzanine card, said first and said second anisotropic materials respectively electrically coupling said circuit board to said first wiring board, and electrically coupling said first wiring board and said mezzanine card.

18. A method according to claim 16, further comprising providing a second wiring board electrically coupling at least a portion of a second plurality of conductive traces disposed on a second side of said mezzanine card with at least a portion of said electrical contacts of said connector footprint.

19. A method according to claim 18, said second wiring board electrically coupling at least a portion of said second plurality of conductive traces disposed on said mezzanine card with at least a portion of electrical contacts of said connector footprint via a third wiring board and said first wiring board.

20. A method according to claim 19, further comprising providing an anisotropic conductive material disposed between at least a portion of said mezzanine card and at least a portion of said second wiring board, said anisotropic material electrically coupling at least a portion of said second plurality of conductive traces to a plurality of electrical contacts disposed on said second wiring board.
